(19) United States
(12) Patent Application Publication
(10) Pub. No.: US 2026/0265544 A1
(43) Pub. Date: Sep. 10, 2026

(54) PIGMENT COMPOSITION, COLORING COMPOSITION FOR COLOR FILTER, AND COLOR FILTER

(71) Applicant: DIC Corporation, Tokyo (JP)

(72) Inventors: Ayaka Yamaji, Sakura-shi (JP); Yuta Hidaka, Sakura-shi (JP)

(73) Assignee: DIC Corporation, Tokyo (JP)

(21) Appl. No.: 19/471,467

(22) PCT Filed: Apr. 4, 2024
(86) PCT No.: PCT/JP2024/013871

§ 371 Date: Oct. 1, 2025

(30) Foreign Application Priority Data
Apr. 18, 2023 (JP) 2023-067714

(51) Int. Cl. C09D 5/32; C08K 5/00; C09D 7/41; G02B 5/22

(52) U.S. Cl. CPC C09D 5/32; C09D 7/41; G02B 5/223; C08K 5/0041

(57) ABSTRACT

An object of the present invention is to provide a pigment composition capable of particularly expanding a blue color gamut in a red pixel portion, a coloring composition for a color filter containing the pigment composition, and a color filter. Specifically, the pigment composition of the present invention contains at least one dye selected from the group consisting of Solvent Red 122, Solvent Red 52, Solvent Orange 99, Solvent Red 135, Solvent Red 225, Solvent Orange 116, Solvent Red 146, and Solvent Red 119, and C.I. Pigment Red 177. The coloring composition for a color filter of the present invention contains the pigment composition, a solvent, and a binder resin. The color filter of the present invention has a pixel portion including the pigment composition.

### TECHNICAL FIELD

The present invention relates to a pigment composition, a coloring composition for a color filter containing the same, and a color filter including a pixel portion including the pigment composition.

### BACKGROUND ART

A color filter is a member that achieves color display on a display by converting white backlight into red, green, and blue lights. In the specification of a high color reproduction display, high color reproduction is required for a red colorant for a color filter. In order to achieve high color reproduction, a reproducible color gamut needs to be expanded. It has been revealed that in a red pixel portion, an increase in chromaticity x, that is, the use of a bluish red colorant can expand a color gamut.

In recent years, C.I. Pigment Red 269 has been developed as a high-brightness bluish red colorant. However, C.I. Pigment Red 269 has disadvantages, such as low contrast and low heat resistance, and hence a color filter suitable for practical use has not been developed.

Meanwhile, C.I. Pigment Red 177 used as a bluish red colorant in a conventional color filter product has features, such as excellent contrast and heat resistance, but has insufficient blueness and does not sufficiently achieve high color reproduction.

For example, PTL 1 includes a coloring composition for a color filter used in a red pixel portion as described above. In PTL 1, there is a coloring composition for a color filter that contains a colorant, a metal complex compound, a binder resin, and an organic solvent and in which the colorant contains a specific naphthol azo pigment and a metal complex compound having a specific central metal.

### CITATION LIST

### Patent Literature

PTL 1: Japanese Unexamined Patent Application Publication No. 2016-114940

### SUMMARY OF INVENTION

### Technical Problem

In PTL 1, a metal complex dye is used to improve contrast, but an effect on color gamut expansion is not recognized. For expansion of the color gamut of a red colorant in a blue direction, it is considered that alteration of the skeleton itself of a pigment caused by replacement of C.I. Pigment Red 177 by Pigment Red 269 is necessary. In the prior art other than PTL 1, C. I. Pigment Red 177 has been used as a bluish red colorant for a color filter, but had a problem in that the color gamut of high color reproduction cannot be developed due to insufficient blueness.

Accordingly, an object of the present invention is to provide a pigment composition capable of particularly expanding a blue color gamut in a red pixel portion when C.I. Pigment Red 177 having excellent contrast and heat resistance is contained, a coloring composition for a color filter containing the pigment composition, and a color filter.

### Solution to Problem

The inventors of the present invention have investigated, and as a result, found that the use of C.I. Pigment Red 177 and a specific dye in combination can particularly expand a blue color gamut in a red pixel portion. The blue color gamut in the present invention refers a color gamut in which x at y=0.312 is larger than 0.6861 in chromaticity coordinates represented by chromaticity x and y measured under a C light source on a color filter produced by mixing a pigment composition in which C. I. Pigment Red 177 and a dye are mixed and C.I. Pigment Yellow 139 at a specific ratio.

In the present invention, a mechanism of expanding a blue color gamut is presumed as described below. The addition of a specific dye can make up for insufficient absorption on a long wavelength side due to C.I. Pigment Red 177. Thus, it is considered that the blue color gamut can be expanded.

That is, the present invention is as follows.

[1] A pigment composition containing at least one dye selected from the group consisting of Solvent Red 122, Solvent Red 52, Solvent Orange 99, Solvent Red 135, Solvent Red 225, Solvent Orange 116, Solvent Red 146, and Solvent Red 119, and C.I. Pigment Red 177.

[2] A coloring composition for a color filter containing the pigment composition according to [1], a solvent, and a binder resin.

[3] A color filter including a pixel portion including the pigment composition according to [1].

### Advantageous Effects of Invention

A pigment composition of the present invention can particularly expand a blue color gamut in a red pixel portion, and expand a region that can be represented by chromaticity x and y. Accordingly, the pigment composition is useful as a coloring composition for a color filter that forms a red pixel portion in the color filter.

### BRIEF DESCRIPTION OF DRAWINGS

FIG. 1 is a graph in which values of chromaticity x and y measured under a C light source in the evaluation of properties of color filters in Examples are plotted.

### DESCRIPTION OF EMBODIMENTS

### [Pigment Composition]

A pigment composition of the present invention contains at least one dye selected from the group consisting of Solvent Red 122 (SR122), Solvent Red 52 (SR52), Solvent Orange 99 (SO99), Solvent Red 135 (SR135), Solvent Red 225 (SR225), Solvent Orange 116 (SO116), Solvent Red 146 (SR146), and Solvent Red 119 (SR119), and C.I. Pigment Red 177 (PR177) as an anthraquinone pigment. The pigment composition of the present invention is not particularly limited as long as it contains the dye and PR177, but may contain a dye and a pigment other than the dye and PR177. One kind of the dyes may be used alone, or two or more kinds thereof may be used in combination.

It is preferable that PR177 used in the present invention be micronized and used, but a micronization method is not particularly limited. For example, any of wet grinding, dry grinding, and solution deposition may be used. The primary particle diameter of the micronized pigment is preferably 20 nm or more since dispersion in a colorant carrier is satisfactory. In addition, it is preferably 100 nm or less since a color filter having a high contrast ratio can be formed. It is particularly preferably within the range of 25 to 85 nm. At the time of micronizing PR177, a resin may be added, if necessary. Examples of the resin include a natural resin, a modified natural resin, a synthetic resin, and a synthetic resin modified with a natural resin.

In particular, the dye in the present invention is preferably Solvent Red 122, Solvent Red 52, Solvent Orange 99, Solvent Red 135, Solvent Red 225, or Solvent Orange 116, and particularly preferably Solvent Red 122, from the viewpoint of a high effect on blue color gamut expansion.

The dye in the present invention is preferably dissolved at room temperature in an organic solvent generally used in the production of a color filter, such as propylene glycol monomethyl ether acetate. Further, during the formation of a coating film of a color filter, the dye is more preferably a dye to be dissolved in a colorant carrier in heating the coating film at 230° C. for 1 hour. When such a dye having satisfactory solubility is used, a coloring composition for a color filter having excellent brightness and contrast can be obtained.

When a color gamut close to the DCI specification is preferred, the proportion of the dye (in the case of containing two or more dyes, the sum of the dyes) in the pigment composition of the present invention is 0.5 to 8 mass %, and desirably 2 to 8 mass %. When a blue color gamut is more preferred, for example, the proportion of the dye is desirably 30 to 40 mass %. When a blue color gamut is further preferred (BT. 2020 specification, etc.), for example, the proportion of the dye is desirably 80 to 90 mass %.

The pigment composition of the present invention may contain a red organic pigment other than PR177, a blue organic pigment, and a yellow organic pigment. Examples of the red organic pigment other than PR177 include C.I. Pigment Red 1, 2, 3, 4, 5, 6, 7, 8, 9, 12, 14, 15, 16, 17, 21, 22, 23, 31, 32, 37, 38, 41, 47, 48, 48:1, 48:2, 48:3, 48:4, 49, 49:1, 49:2, 50:1, 52:1, 52:2, 53, 53:1, 53:2, 53:3, 57, 57:1, 57:2, 58:4, 60, 63, 63:1, 63:2, 64, 64:1, 68, 69, 81, 81:1, 81:2, 81:3, 81:4, 83, 88, 90:1, 101, 101:1, 104, 108, 108:1, 109, 112, 113, 114, 122, 123, 144, 146, 147, 149, 151, 166, 168, 169, 170, 172, 173, 174, 175, 176, 178, 179, 181, 184, 185, 187, 188, 190, 193, 194, 200, 202, 206, 207, 208, 209, 210, 214, 216, 220, 221, 224, 230, 231, 232, 233, 235, 236, 237, 238, 239, 242, 243, 245, 247, 249, 250, 251, 253, 254, 255, 256, 257, 258, 259, 260, 262, 263, 264, 265, 266, 267, 268, 269, 270, 271, 272, 273, 274, 275, and 276.

Examples of the blue organic pigment include C.I. Pigment Blue 1, 1:2, 9, 14, 15, 15:1, 15:2, 15:3, 15:4, 15:6, 16, 17, 19, 25, 26, 27, 28, 29, 33, 35, 36, 56, 56:1, 60, 61, 61:1, 62, 63, 64, 66, 67, 68, 71, 72, 73, 74, 75, 76, 78, 79, and 80.

Examples of the yellow organic pigment include C.I. Pigment Yellow 1, 1:1, 2, 3, 4, 5, 6, 9, 10, 12, 13, 14, 16, 17, 24, 31, 32, 34, 35, 35:1, 36, 36:1, 37, 37:1, 40, 41, 42, 43, 48, 53, 55, 61, 62, 62:1, 63, 65, 73, 74, 75, 81, 83, 87, 93, 94, 95, 97, 100, 101, 104, 105, 108, 109, 110, 111, 116, 117, 119, 120, 126, 127, 127:1, 128, 129, 133, 134, 136, 138, 139, 142, 147, 148, 150, 151, 153, 154, 155, 157, 158, 159, 160, 161, 162, 163, 164, 165, 166, 167, 168, 169, 170, 172, 173, 174, 175, 176, 180, 181, 182, 183, 184, 185, 188, 189, 190, 191, 191:1, 192, 193, 194, 195, 196, 197, 198, 199, 200, 202, 203, 204, 205, 206, 207, 208, and 229.

The red organic pigment other than PR177, the blue organic pigment, and the yellow organic pigment can be used within the range that does not impair the effects of the present invention. The proportion of the pigments in all the pigments in the pigment composition of the present invention is, for example, 20 mass % or less, and preferably 10 mass % or less.

A dye other than the above-mentioned dye in the present invention may be used. Examples of a red dye serving as such a dye include Solvent Red 109, Solvent Red 111, Solvent Red 124, Solvent Red 149, Solvent Red 150, Solvent Red 168, Solvent Red 169, Solvent Red 172, Solvent Red 179, Solvent Red 195, Solvent Red 196, Solvent Red 197, Solvent Red 207, Solvent Red 222, Solvent Red 227, Solvent Red 23, Solvent Red 24, Solvent Red 25, Solvent Red 27, Solvent Red 3, Solvent Red 312, Solvent Red 313, Solvent Red 49, and Solvent Red 8. Examples of an orange dye include Solvent Orange 107, Solvent Orange 14, Solvent Orange 3, Solvent Orange 54, Solvent Orange 60, Solvent Orange 62, Solvent Orange 63, and Solvent Orange 86. Examples of a yellow dye include Solvent Yellow 114, Solvent Yellow 131, Solvent Yellow 135, Solvent Yellow 14, Solvent Yellow 157, Solvent Yellow 16, Solvent Yellow 160, Solvent Yellow 163, Solvent Yellow 167, Solvent Yellow 176, Solvent Yellow 179, Solvent Yellow 185, Solvent Yellow 189, Solvent Yellow 2, Solvent Yellow 21, Solvent Yellow 33, Solvent Yellow 43, Solvent Yellow 44, Solvent Yellow 56, Solvent Yellow 65, Solvent Yellow 82, Solvent Yellow 85, Solvent Yellow 93, and Solvent Yellow 98. Further, examples of a green dye include Solvent Green 28, Solvent Green 3, Solvent Green 5, and Solvent Green 7.

The other dyes can be used within the range that does not impair the effects of the present invention. The proportion of the other dyes in all the dyes in the pigment composition of the present invention is, for example, 20 mass % or less, and preferably 10 mass % or less.

The primary particle diameter of the pigments in the pigment composition of the present invention is, for example, 20 to 150 nm, and preferably 20 to 100 nm. When the primary particle diameter of the pigment is more than 150 nm, dispersion stability is deteriorated, and as a result, light scattering may occur easily. The pigment composition of the present invention may be subjected to micronization treatment. The micronization treatment may be usually performed by a pulverization process, such as dry pulverization or wet pulverization.

For the primary particle diameter of the pigment in the pigment composition of the present invention, the pigment composition is dispersed in a solvent, such as cyclohexanone, the dispersion solution is applied to a colloidal membrane and photographed with a transmission electron microscope (TEM) to obtain an image. The sizes of 1,000 particles in the photographed image are measured, and the average value is regarded as the primary particle diameter of the pigment.

In the pigment composition of the present invention, a variety of derivatives may be used in combination if necessary, in addition to the pigment and the dye to improve dispersibility. As a substituent in such derivatives with respect to the skeleton of the pigment and the dye, for example, a substituent in which a sulfonic acid group, a sulfonamide group and a quaternary salt thereof, a phthalimidomethyl group, a dialkylaminoalkyl group, a hydroxy group, a carboxy group, an amide group, or the like is bound directly or via an alkyl group, an aryl group, a heterocyclic group, or the like to the pigment skeleton.

The pigment composition of the present invention may be produced by mixing and stirring (dry blending) the pigment containing PR177 and a dye powder, such as Solvent Red 122, or by mixing the dispersion solution of the pigment and the dispersion solution of the dye.

### [Coloring Composition for Color Filter]

The coloring composition for a color filter of the present invention contains the pigment composition of the present invention, a solvent, and a binder resin. In addition, a resin-based dispersant or the like may be used for the coloring composition if necessary.

As the solvent, an organic solvent is usually used. Examples of such an organic solvent include diisopropyl ether, mineral spirit, n-pentane, amyl ether, ethyl caprylate, n-hexane, diethyl ether, isoprene, ethyl isobutyl ether, butyl stearate, n-octane, Varsol #2, Apco #18 solvent, diisobutylene, amyl acetate, butyl acetate, Apco thinner, butyl ether, diisobutyl ketone, methyl cyclohexene, methyl nonyl ketone, propyl ether, dodecane, Socal solvent No. 1 and No. 2, amyl formate, dihexyl ether, diisopropyl ketone, Solvesso #150, (n, sec, t-)butyl acetate, hexene, Shell TS28 Solvent, butyl chloride, ethyl amyl ketone, ethyl benzoate, amyl chloride, ethylene glycol diethyl ether, ethyl orthoformate, methoxymethylpentanone, methyl butyl ketone, methyl hexyl ketone, methyl isobutyrate, benzonitrile, ethyl propionate, methyl cellosolve acetate, methyl isoamyl ketone, n-amyl methyl ketone (2-heptanone), methyl isobutyl ketone, propyl acetate, bicyclohexyl, diethylene glycol monoethyl ether acetate, dipentene, methoxymethylpentanol, methyl amyl ketone, methyl isopropyl ketone, propyl propionate, propylene glycol t-butyl ether, methyl ethyl ketone, methyl cellosolve, ethyl cellosolve, ethyl cellosolve acetate, carbitol, cyclohexanone, ethyl acetate, propylene glycol, propylene glycol monomethyl ether, propylene glycol monomethyl ether acetate, propylene glycol monoethyl ether, propylene glycol monoethyl ether acetate, dipropylene glycol monoethyl ether, dipropylene glycol dimethyl ether, dipropylene glycol monomethyl ether, dipropylene glycol monomethyl ether acetate, 3-methoxypropionic acid, 3-ethoxypropionic acid, methyl 3-ethoxypropionate, ethyl 3-ethoxypropionate, methyl 3-methoxypropionate, ethyl 3-methoxypropionate, propyl 3-methoxypropionate, butyl 3-methoxypropionate, diglyme, ethylene glycol acetate, ethyl carbitol, butyl carbitol, ethylene glycol monobutyl ether, 3-methoxybutanol, 3-methyl-3-methoxybutanol, tripropylene glycol methyl ether, and ethyl lactate.

In order to prepare the coloring composition of the present invention, one kind of the solvents may be used alone, or two or more kinds thereof may be used in combination. In the coloring composition, the solvent is used usually in an amount of 500 to 900 parts by mass, and preferably 600 to 800 parts by mass, with respect to 100 parts by mass of the pigment composition.

Examples of the binder resin include a thermoplastic resin and a thermosetting resin. The resin is preferably a transparent resin having a spectral transmission of preferably 80% or more, and more preferably 95% or more at a whole wavelength region of 400 to 700 nm as a visible light region.

Examples of the thermoplastic resin include an acrylic resin, a butyral resin, a styrene-maleic acid copolymer, chlorinated polyethylene, chlorinated polypropylene, polyvinyl chloride, vinyl chloride-vinyl acetate copolymer, polyvinyl acetate, a polyurethane-based resin, a polyester resin, a vinyl-based resin, an alkyd resin, a polystyrene resin, a polyamide resin, a rubber-based resin, a cyclized rubber-based resin, celluloses, polyethylene (HDPE and LDPE), polybutadiene, and a polyimide resin. Examples of the thermosetting resin include an epoxy resin, a benzoguanamine resin, a rosin-modified maleic acid resin, a rosin-modified fumaric acid resin, a melamine resin, a urea resin, and a phenolic resin.

The proportion of the binder resin is, for example, 30 to 500 parts by mass, and preferably 40 to 400 parts by mass, with respect to 100 parts by mass of the pigment composition.

When the pigment composition is dispersed in the solvent, a resin-based dispersant may be used to improve dispersibility and improve dispersion stability. This resin-based dispersant has a function of bonding an anchor moiety to an organic pigment and extending a compatible part toward a dispersion medium to form a dispersion, and is different from an alkali-soluble resin used in the preparation of a photo-sensitive composition to be described below or a photo-polymerizable monomer. In addition to the resin-based dispersant, rosin, a surfactant, and the like may be further contained. These components may or may not be used in the surface treatment of the pigment (so-called surface treatment). A method for the surface treatment of the pigment may be a known method, such as treatment with rosin, treatment with a surfactant, treatment with a solvent, or treatment with a resin.

Examples of the resin-based dispersant include a compound having a high polymer chain, such as a polyurethane resin, polyethyleneimine, polyoxyethylene glycol diester, an acrylic resin, and a polyester resin. Of these, a polyester resin-based dispersant and/or an acrylic resin-based dispersant are preferred from the viewpoint of dispersibility, heat resistance, and light resistance.

Specific examples of the resin-based dispersants include, as product name, AJISPER (manufactured by Ajinomoto Fine-Techno Co., Inc.), EFKA (manufactured by BASF), DISPERBYK (manufactured by BYK), BYKLPN (manufactured by BYK), DISPARLON (manufactured by Kusumoto Chemicals, Ltd.), SOLSPERSE (manufactured by Lubrizol Corporation), KP (manufactured by Shin-Etsu Chemical Co., Ltd.), and POLYFLOW (manufactured by KYOEISHA CHEMICAL CO., LTD.). One kind of the dispersants may be used, or two or more kinds thereof may be used in any combination at any ratio.

The proportion of the resin-based dispersant is, for example, 30 to 60 parts by mass, and preferably 38 to 50 parts by mass, with respect to 100 parts by mass of the pigment composition.

The coloring composition can be prepared by stirring and mixing the pigment composition of the present invention, the solvent, and the resin-based dispersant to be added if necessary. If necessary, shaking is performed for a necessary time in the presence of various types of grinding media, such as beads or rods, and the media are dispersed by filtration and the like. Thus, the coloring composition can be prepared. The coloring composition of the present invention is used in a red pixel portion of a color filter. It is preferable that a coloring composition containing a yellow pigment, such as Pigment Yellow 139 be mixed in the coloring composition of the present invention to form a red pixel that is a preferable color tone (toning).

A photo-sensitive composition is usually prepared to form a red pixel portion using the coloring composition by a photolithography process, or the like. The photo-sensitive composition contains, for example, the coloring composition, an alkali-soluble resin, a photo-polymerizable monomer, and a photopolymerization initiator.

Examples of the alkali-soluble resin include a resin having a carboxy group or a hydroxy group exhibiting acidity, such as a novolac type phenolic resin, an alkyl (meth)acrylate-(meth)acrylic acid copolymer, a styrene-(meth)acrylic acid copolymer, and a styrene-maleic acid copolymer.

Examples of the photo-polymerizable monomer include bifunctional monomers, such as 1,6-hexanediol di(meth)acrylate, ethylene glycol di(meth)acrylate, neopentyl glycol di(meth)acrylate, triethylene glycol di(meth)acrylate, bis[(meth)acryloxyethoxy] bisphenol A, and 3-methylpentanediol di(meth)acrylate; polyfunctional monomers having a relatively small molecular weight, such as trimethylolpropane tri(meth)acrylate, pentaerythritol tri(meth)acrylate, tri(meth)acrylate of tris(2-hydroxyethyl)isocyanurate, dipentaerythritol hexa(meth)acrylate, dipentaerythritol penta(meth)acrylate, and ditrimethylolpropane tetra(meth)acrylate; and polyfunctional monomers having a relatively large molecular weight, such as polyester acrylate, polyurethane acrylate, and polyether acrylate.

Examples of the polymerization initiator include acetophenone, benzophenone, benzyl dimethyl ketal, benzoyl peroxide, 2-chlorothioxanthone, 1,3-bis(4′-azidobenzal)-2-propane, 1,3-bis(4-azidobenzal)-2-propane-2′-sulfonic acid, 4,4′-diazidostylbene-2,2′-disulfonic acid, and 1-[9-ethyl-6-[2-methyl-4-(2,2-dimethyl-1,3-dioxolanyl) methoxybenzoyl]-9.H.-carbazol-3-yl]-1-(O-acetyloxime) ethanone.

As the photo-sensitive composition, a photo-sensitive composition for forming a pixel portion can be obtained by adding the alkali-soluble resin and the photo-polymerizable monomer in a total amount of 3 to 20 parts with respect to 1 part of the pigment composition of the present invention, the photopolymerization initiator in an amount of 0.05 to 3 parts with respect to 1 part of the photo-polymerizable monomer, and if necessary, the solvent used in the preparation of the coloring composition described above, and homogeneously stirring and dispersing the mixture.

### [Color Filter]

A color filter of the present invention has a pixel portion including the pigment composition of the present invention. The color filter of the present invention can be produced using the photo-sensitive composition containing the coloring composition of the present invention by a known method.

A typical method for producing a color filter is a photolithography method. In the method, for the red pixel portion, the photo-sensitive composition containing the coloring composition of the present invention is applied to a transparent substrate, such as a glass for a color filter, heat-dried (pre-baked), and then subjected to pattern exposure by irradiation with ultraviolet light through a photomask, to cure a photo-curable compound at a portion corresponding to a pixel portion, such as a red pixel portion, an unexposed portion is developed with a developer, a non-pixel portion is removed, and the pixel portion is secured to the transparent substrate. By this method, the red pixel portion formed of the cured coloring coating of the photo-sensitive composition is formed on the transparent substrate. Green (G) and blue (B) pixel portions can also be produced from a photo-sensitive composition prepared from a corresponding organic pigment of each color in the same manner as described above.

In addition to the photolithography method, a method for applying a photo-sensitive composition to a transparent substrate includes a spin coating method, a roll-coating method, a slit coating method, or an inkjet method.

A condition of drying the coating film of the photo-sensitive composition applied to the transparent substrate varies depending on the kind, blending ratio, and the like of each component. The condition typically includes 50 to 150° C. and about 1 to 15 minutes. This heating treatment is generally referred to as pre-baking. As light used in photo-curing the photo-sensitive composition, ultraviolet light having a wavelength range of 200 to 500 nm or visible light is preferably used. A variety of light sources that emit light having this wavelength range can be used. Examples of a development method using the light sources that emit light having this wavelength range include a liquid deposition method, a dipping method, and a spray method. After the exposure and the development for the photo-sensitive composition, the transparent substrate in which a pixel portion of required color is formed is cleaned with water and dried. The thus obtained color filter is subjected to heating treatment (post-baking) at 90 to 280° C. for a predetermined time with a heating device, such as a hot plate or an oven, to remove a volatile component in the coloring coating film and at the same time, thermally cure the unreacted photo-curable compound remaining in the cured coloring coating of the photo-sensitive composition. Thus, a color filter is completed.

The color filter can be obtained by a method in which the coated film of the pixel portion is formed by the above-mentioned method, a liquid crystal material is enclosed between a pair of parallel transparent electrodes, the transparent electrodes are divided into discrete fine sections, and a color filter-colored pixel portions of any one color selected from red (R), green (G), and blue (B) is alternately provided in a pattern on each of fine sections divided in a lattice shape by a black matrix on the transparent electrodes, or by forming a color filter-colored pixel portion on the substrate and then providing transparent electrodes.

### Examples

Hereinafter, the present invention will be more specifically described on the basis of Examples, but the present invention is not limited to the following examples. In these examples, “part(s)” represents “part(s) by mass”.

### [Preparation of Pigment Composition]

Pigment Red 177 and a dye or a pigment listed in Table 1 below were mixed and stirred at a ratio listed in Table 1 to obtain pigment compositions 1 to 17. In the pigment composition 17, Pigment Red 269 was used instead of Pigment Red 177.

TABLE 1

| | | Dye or | Pigment | Ratio of dye |
|---|---|---|---|---|
| | Pigment | pigment | ratio | or pigment |
| Pigment composition 1 | PR177 | SR122 | 95 | 5 |
| Pigment composition 2 | PR177 | SR52 | 95 | 5 |
| Pigment composition 3 | PR177 | SO99 | 95 | 5 |
| Pigment composition 4 | PR177 | SR135 | 95 | 5 |
| Pigment composition 5 | PR177 | SR225 | 95 | 5 |
| Pigment composition 6 | PR177 | SO116 | 95 | 5 |
| Pigment composition 7 | PR177 | SR146 | 95 | 5 |
| Pigment composition 8 | PR177 | SR119 | 95 | 5 |
| Pigment composition 9 | PR177 | SR122 | 90 | 10 |
| Pigment composition 10 | PR177 | SR122 | 80 | 20 |
| Pigment composition 11 | PR177 | SR122 | 60 | 40 |
| Pigment composition 12 | PR177 | SR122 | 40 | 60 |
| Pigment composition 13 | PR177 | SR122 | 20 | 80 |
| Pigment composition 14 | PR177 | None | 100 | 0 |
| Pigment composition 15 | PR177 | PB15:6 | 95 | 5 |
| Pigment composition 16 | None | SR122 | 0 | 100 |
| Pigment composition 17 | PR269 | None | 100 | 0 |

### [Preparation of Coloring Composition for Evaluation of Properties of Color Filter]

1.82 Parts of a mixture in which each of the pigment compositions produced as listed in Table 1 and Pigment Yellow 139 were mixed at a blending ratio of the respective pigment composition to Pigment Yellow 139 of 9:1 to 1:9, 3.63 parts of BYK LPN-21116 (manufactured by BYK), and 12.75 parts of propylene glycol monomethyl ether acetate were mixed, zirconia beads having a diameter of 0.3 to 0.4 mm were added, the mixture was dispersed with a paint conditioner (manufactured by TOYO SEIKI SEISAKU-SHO, LTD.) for 3 hours to obtain coloring compositions of Examples 1-1 to 1-13 and Comparative Examples 1-1 to 1-2.

### [Preparation of Color Filter for Evaluation]

Each of the coloring compositions was applied to a soda glass substrate with a spin coater, dried at 90° C. for 3 minutes, and heated (post-baked) at 230° C. for 1 hour. A coating film having a dried film thickness of about 3.5 μm was obtained by adjusting the rotation number of the spin coater. The film thickness was measured with a white light interference microscope (VS1330) manufactured by Hitachi High-Tech Science Corporation. Thus, a plurality of color filters for evaluation having different composition ratios of the pigment composition and Pigment Yellow 139 were produced.

[Evaluation of Properties of Color Filter: Chromaticity x at Specific Chromaticity y]

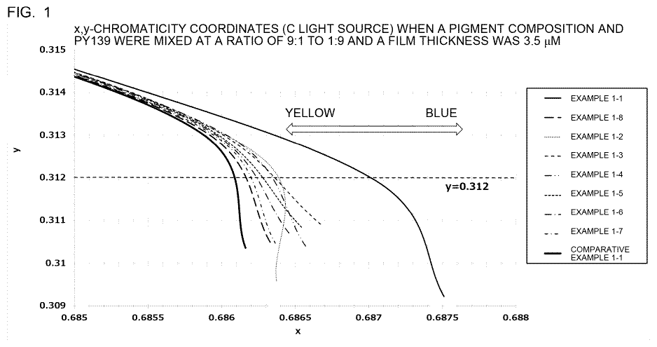

FIG. 1 is a graph obtained by plotting values of chromaticity x and y measured under a C light source with a spectrophotometer (U3900 manufactured by Hitachi High-Tech Science Corporation) on the color filters produced as described above. FIG. 1 illustrates data of Examples 1-1 to 1-13 and Comparative Example 1-1. Table 2 below lists values of x calculated when chromaticity y is 0.312 in Examples 1-1 to 1-13 and Comparative Examples 1-1 to 1-2. By comparison between the values of chromaticity x at specific chromaticity y, the expansion of the color gamut relative to Pigment Red 177 was evaluated with a chromaticity difference Δx. The Δx (relative to PR177) that is positive shows that chromaticity shifts in a blue direction, that is, the color gamut expands. In Comparative Example 1-2, chromaticity y did not reach 0.312, and hence evaluation was not performed.

TABLE 2

| | | Value | Δx |
|---|---|---|---|
| | | of x at | (relative to |
| | Pigment composition | y = 0.312 | PR177) |
| Example 1-1 | Pigment composition 1 | 0.68700 | 0.00090 |
| Example 1-2 | Pigment composition 2 | 0.68639 | 0.00029 |
| Example 1-3 | Pigment composition 3 | 0.68636 | 0.00026 |
| Example 1-4 | Pigment composition 4 | 0.68632 | 0.00022 |
| Example 1-5 | Pigment composition 5 | 0.68628 | 0.00018 |
| Example 1-6 | Pigment composition 6 | 0.68622 | 0.00012 |
| Example 1-7 | Pigment composition 7 | 0.68620 | 0.00010 |
| Example 1-8 | Pigment composition 8 | 0.68618 | 0.00008 |
| Example 1-9 | Pigment composition 9 | 0.68757 | 0.00147 |
| Example 1-10 | Pigment composition 10 | 0.68760 | 0.00150 |
| Example 1-11 | Pigment composition 11 | 0.68780 | 0.00170 |
| Example 1-12 | Pigment composition 12 | 0.68780 | 0.00170 |
| Example 1-13 | Pigment composition 13 | 0.68780 | 0.00170 |
| Comparative | Pigment composition 14 | 0.68610 | 0 |
| Example 1-1 | | | |
| Comparative | Pigment composition 15 | y did not | — |
| Example 1-2 | | reach | |
| | | 0.312 | |

As seen from Table 2, Ax (relative to PR177) was positive in the pigment compositions containing PR177 and any dye of SR122, SR52, SO99, SR135, SR225, SO116, SR146, and SR119 in Examples 1-1 to 1-13. In particular, a combination of PR177 and Solvent Red 122 shows a significant effect on color gamut expansion. Accordingly, the pigment composition of the present invention can particularly expand a blue color gamut in a red pixel portion. Meanwhile, when of similar blue materials, a blue pigment, such as Pigment Blue 15:6 (PB15:6) of Comparative Example 1-2, was added, chromaticity was not able to be adjusted in a target direction.

### (Preparation of Coloring Composition for Evaluation of Heat Resistance)

1.82 Parts of the pigment composition produced at the pigment ratio shown in Table 1 above, 3.63 parts of BYK LPN-21116 (manufactured by BYK), and 12.75 parts of propylene glycol monomethyl ether acetate were mixed, zirconia beads having a diameter of 0.3 to 0.4 mm were added, and the mixture was dispersed with a paint conditioner (manufactured by TOYO SEIKI SEISAKU-SHO, LTD.) for 3 hours to obtain coloring compositions of Examples 2-1 to 2-11 and Comparative Examples 2-1 to 2-2.

### (Evaluation of Heat Resistance of Pigment Composition)

Each of the coloring compositions was applied to a soda glass substrate with a spin coater so that the dried film thickness was 3.5 μm, then dried at 90° C. for 3 minutes, and allowed to cool to produce a coating film substrate. The chromaticity ([L*(1), a*(1), b*(1)]) of the obtained coating film under a C light source was measured with a spectrophotometer (U3900 manufactured by Hitachi High-Tech Science Corporation). After that, in a heat resistance test, the coating film was heated (post-baked) at 230° C. for 1 hour, the chromaticity ([L*(2), a*(2), b*(2)]) under a C light source was measured, and a color difference ΔE was determined by the following formula, and evaluated according to the following four ranks.

$$Δ E = √ ( ( L * ( 2 ) - L * ( 1 ) ) 2 + ( a * ( 2 ) - a * ( 1 ) ) 2 + ( b * ( 2 ) - b * ( 1 ) ) 2 )$$

### [Evaluation]

⊚: A difference ΔE relative to Comparative Example 2-2 is less than 20% (highly satisfactory)
◯: A difference ΔE relative to Comparative Example 2-2 is 20% or more and less than 50% (satisfactory)
Δ: A difference ΔE relative to Comparative Example 2-2 is 50% or more and less than 100% (poor)
x: A difference ΔE relative to Comparative Example 2-2 is 100% or more (highly poor)

TABLE 3

| | | Heat | ΔΕ ratio (relative to | |
|---|---|---|---|---|
| Example | Pigment composition | resistance ΔΕ | Comparative Example 2-2) | |
| Example 2-1 | Pigment composition 1 | 1.13 | 17% | ⊚ |
| Example 2-2 | Pigment composition 3 | 1.30 | 20% | ◯ |
| Example 2-3 | Pigment composition 4 | 1.40 | 21% | ◯ |
| Example 2-4 | Pigment composition 5 | 1.35 | 20% | ◯ |
| Example 2-5 | Pigment composition 7 | 1.00 | 15% | ⊚ |
| Example 2-6 | Pigment composition 8 | 1.83 | 27% | ◯ |
| Example 2-7 | Pigment composition 9 | 2.15 | 32% | ◯ |
| Example 2-8 | Pigment composition 10 | 1.94 | 29% | ◯ |
| Example 2-9 | Pigment composition 11 | 1.51 | 23% | ◯ |
| Example 2-10 | Pigment composition 12 | 1.63 | 24% | ◯ |
| Example 2-11 | Pigment composition 13 | 2.33 | 35% | ◯ |
| Comparative Example 2-1 | Pigment composition 16 | 3.8 | 57% | Δ |
| Comparative Example 2-2 | Pigment composition 17 | 6.66 | 100% | X |

The smaller value of ΔE ratio shows that a color difference before and after the heat resistance test is smaller, that is, heat resistance is more satisfactory. As seen from Table 3, ΔE (relative to PR269) was highly satisfactory or satisfactory in the pigment compositions containing PR177 and any dye of SR122, SO99, SR135, SR225, SR119, and SR146. Accordingly, the pigment composition of the present invention can maintain satisfactory heat resistance as compared with PR269 conventionally known as a bluish red pigment despite containing a dye.

1. A pigment composition comprising at least one dye selected from the group consisting of Solvent Red 122, Solvent Red 52, Solvent Orange 99, Solvent Red 135, Solvent Red 225, Solvent Orange 116, Solvent Red 146, and Solvent Red 119, and C.I. Pigment Red 177.

2. A coloring composition for a color filter comprising the pigment composition according to claim 1, a solvent, and a binder resin.

3. A color filter comprising a pixel portion including the pigment composition according to claim 1.
